(19) United States
(12) Patent Application Publication
(10) Pub. No.: US 2025/0311179 A1
(43) Pub. Date: Oct. 2, 2025

(54) SHIELD STRUCTURE AND IN-VEHICLE DEVICE

(71) Applicant: Panasonic Automotive Systems Co., Ltd., Kanagawa (JP)

(72) Inventors: Hiroshi SHIINO, Kanagawa Ken (JP); Fumitsugu HATORI, Tokyo To (JP); Yoshikazu HASEGAWA, Kanagawa Ken (JP); Takaharu SHIGETA, Kanagawa Ken (JP)

(73) Assignee: Panasonic Automotive Systems Co., Ltd., Kanagawa (JP)

(21) Appl. No.: 19/096,077

(22) Filed: Mar. 31, 2025

(30) Foreign Application Priority Data
Apr. 1, 2024 (JP) 2024-058906

(51) Int. Cl. H05K 9/00

(52) U.S. Cl. CPC H05K 9/0024

(57) ABSTRACT

A shield structure according to the present disclosure includes a printed circuit board, an elastic member, and a connector shield metal part. The printed circuit board is placed inside a grounded housing. At least one electronic component including a connector connected outside is surface-mounted on the printed circuit board. The elastic member is placed on a mounting surface side of the printed circuit board, inside the housing. The connector shield metal part is placed on the mounting surface side, inside the housing and formed in a shape covering the connector. The connector shield metal part directly contacts and is electrically connected to the housing, and is electrically connected to the connector via the elastic member in a state where the connector shield metal part is attached to the housing.

### CROSS-REFERENCE TO RELATED APPLICATIONS

This application is based upon and claims the benefit of priority from Japanese Patent Application No. 2024-058906, filed on Apr. 1, 2024, the entire contents of which are incorporated herein by reference.

### FIELD

The present disclosure relates to a shield structure and an in-vehicle device.

### BACKGROUND

Conventionally, as an EMC (electromagnetic environmental compatibility) measure of electronic components (board-mounted components) mounted on a printed circuit board, a shield structure in which the surroundings of target board-mounted components such as a connector are physically covered with a metal shield member such as a connector shield metal part is used. For example, JP 2010-109277 A discloses a technology aimed at providing a display-equipped housing that has enhanced noise resistance and that is easily assembled through a process in which connectors are mechanically and electrically connected to each other at the time of assembly.

For example, a shield member used for an EMC measure is configured as a DIP (dual in-line package) component, and has, by being soldered to a printed circuit board by a DIP process, provided GND connection that electrically connects the printed circuit board to the ground (GND) potential.

In such circumstances, these days, there is a demand for a technology that reduces the weight of the soldering process in board mounting and performs the process of board mounting by SMT (surface mount technology), from the viewpoint of stabilizing board mounting quality, reducing costs related to facilities and jigs, and reducing the number of steps of the mounting process. However, in the case where it is attempted to perform the process of board mounting by SMT, there has been room for consideration for how a shield member subjected to GND connection should be electrically connected to a printed circuit board.

A problem to be solved by the present disclosure is to take an EMC measure of board-mounted components in the case where the process of board mounting is performed by SMT.

### SUMMARY

A shield structure according to the present disclosure includes a printed circuit board, an elastic member, and a connector shield metal part. The printed circuit board is placed inside a grounded housing. At least one electronic component including a connector connected outside is surface-mounted on the printed circuit board. The elastic member is placed on a mounting surface side of the printed circuit board, inside the housing. The connector shield metal part is placed on the mounting surface side, inside the housing and formed in a shape covering the connector. The connector shield metal part directly contacts and is electrically connected to the housing, and is electrically connected to the connector via the elastic member in a state where the connector shield metal part is attached to the housing.

### BRIEF DESCRIPTION OF THE DRAWINGS

FIG. 1 is a front view illustrating an example of a configuration of a display device to which a shield structure according to an embodiment is applied;

FIG. 2 is a plan view illustrating an example of the configuration of the display device of FIG. 1;

FIG. 3 is a bottom view illustrating an example of the configuration of the display device of FIG. 1;

FIG. 4 is a left side view illustrating an example of the configuration of the display device of FIG. 1;

FIG. 5 is a right side view illustrating an example of the configuration of the display device of FIG. 1;

FIG. 6 is a rear view illustrating an example of the configuration of the display device of FIG. 1;

FIG. 7 is an exploded perspective view illustrating an example of the configuration of the display device of FIG. 1;

FIG. 8 is a cross-sectional view illustrating an example of a configuration of a shield structure of FIG. 7;

FIG. 9 is an exploded perspective view illustrating another example of the configuration of the display device of FIG. 1;

FIG. 10 is a cross-sectional view illustrating an example of a configuration of a shield structure of FIG. 9;

FIG. 11 is a perspective view illustrating an example of the configuration of the shield structure of FIG. 9; and

FIG. 12 is a cross-sectional view illustrating an example of the configuration of the display device of FIG. 1.

### DETAILED DESCRIPTION

Hereinbelow, embodiments of a shield structure, an in-vehicle device (display device), and a vehicle according to the present disclosure are described with reference to the drawings.

In the description of the present disclosure, constituent elements having the same or substantially the same functions as those already described with respect to previously described drawings are marked with the same reference numerals, and a description may be omitted as appropriate. Further, even when illustrating the same or substantially the same portions, mutual dimensions or ratios may be illustrated differently between drawings. Further, for example, from the viewpoint of ensuring visibility of the drawings, in the description of each drawing, only main constituent elements are marked with reference numerals, and even constituent elements having the same or substantially the same functions as those already described in previously described drawings may not be marked with reference numerals.

In the description of the present disclosure, constituent elements having the same or substantially the same function may be described in a distinctive manner by adding alphanumeric characters to the end of the reference numeral. Alternatively, in the case where a plurality of constituent elements having the same or substantially the same function are not distinguished, the constituent elements may be described in a collective manner by omitting the alphanumeric characters added to the end of the reference numeral.

In the description of the present disclosure, expressions such as orthogonal, horizontal, vertical, parallel, identical, in agreement, and in the same position are not limited to strictly orthogonal, horizontal, vertical, parallel, identical, in agreement, or in the same position, and include cases of being regarded as orthogonal, horizontal, vertical, parallel, identical, in agreement, and in the same position.

A shield structure according to the present

disclosure is applicable to various display devices. As an example, the shield structure according to the present disclosure is applied to a display device as an in-vehicle device such as a navigation device or an audio device. As an example, the shield structure according to the present disclosure may be applied to a display device such as in-vehicle infotainment (IVI), meter control, a HUD (head-up display), or an electronic mirror. Alternatively, the display device to which the shield structure according to the present disclosure is applied may be an external display device installed near a dashboard of a vehicle or the like.

As an example, the display device to which the shield structure according to the present disclosure is applied can perform screen displaying related to various types of vehicle control including autonomous driving, and can accept user operations related to various types of vehicle control. As an example, the display device to which the shield structure according to the present disclosure is applied can perform screen displaying related to route guidance in a navigation system, and can accept user operations related to route guidance such as destination setting. As an example, the display device to which the shield structure according to the present disclosure is applied may be one that performs video (image) output or audio (voice or sound) output with its own device, or may be one that outputs video data or audio data to another display device or an in-vehicle speaker. As an example, the display device to which the shield structure according to the present disclosure is applied includes, for example, a screen and a speaker, but at least one of them may not be provided.

In the case where the shield structure according to the present disclosure is mounted on a display device as an in-vehicle device, the shield structure performs covering or the like on board-mounted components of EMC (electromagnetic environmental compatibility) measure targets (electronic components to be shielded), such as a connector surface-mounted on a printed circuit board that is placed in a housing together with the shield structure, and electrically and magnetically shields the board-mounted components. Further, in addition to performing shielding, the shield structure is electrically connected to each of the housing and the printed circuit board, and subjects the printed circuit board to ground (GND) connection via the housing, which is electrically connected to a chassis of a vehicle or the like and is grounded (for example, functionally grounded).

The display device to which the shield structure according to the present disclosure is applied can, for example, be mounted on various moving bodies such as passenger cars, freight cars, shared cars, motorcycles, and kick scooters.

### First Embodiment

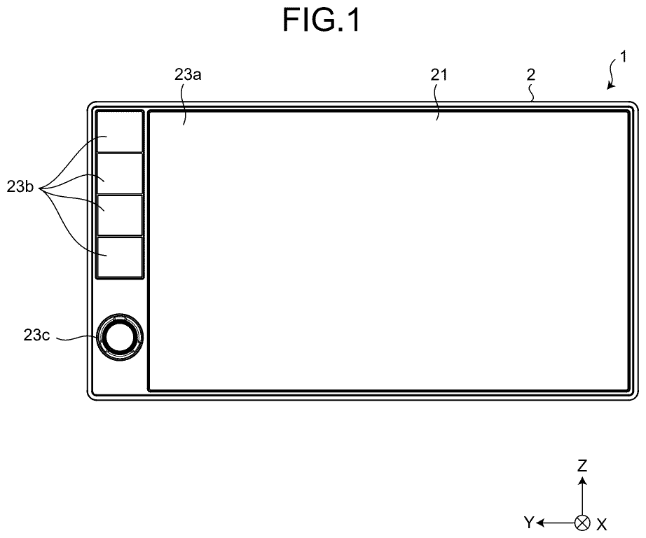

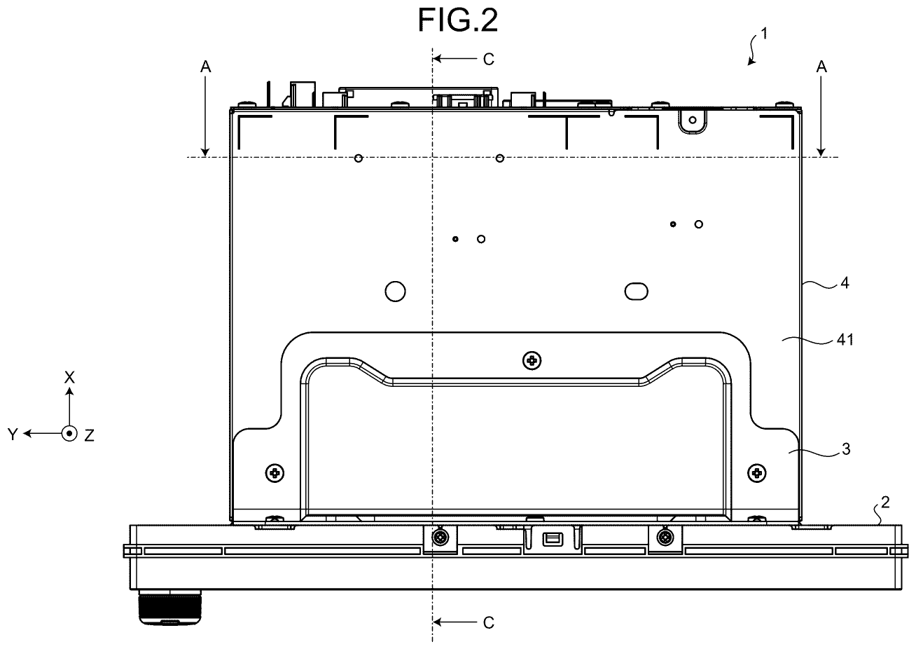

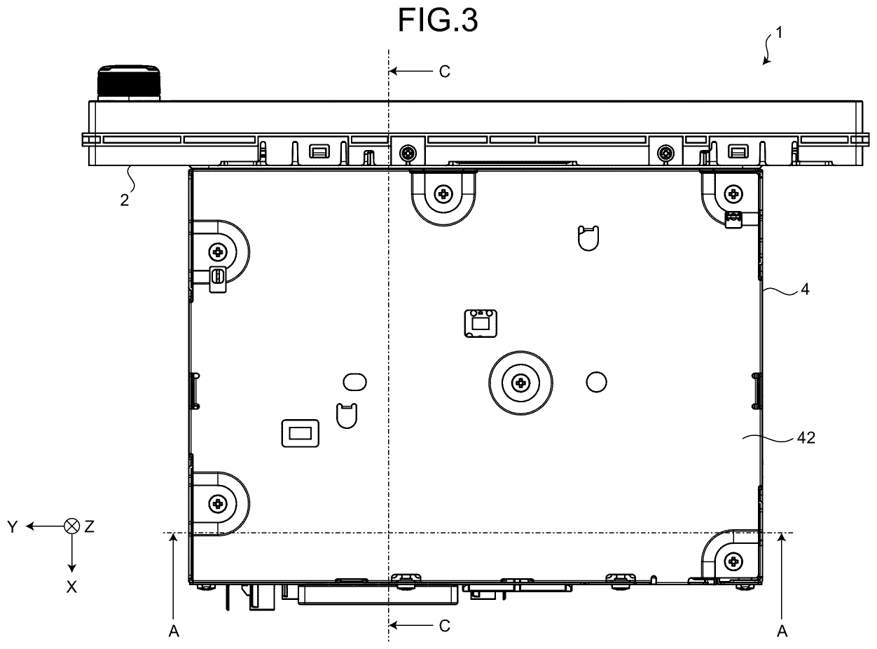

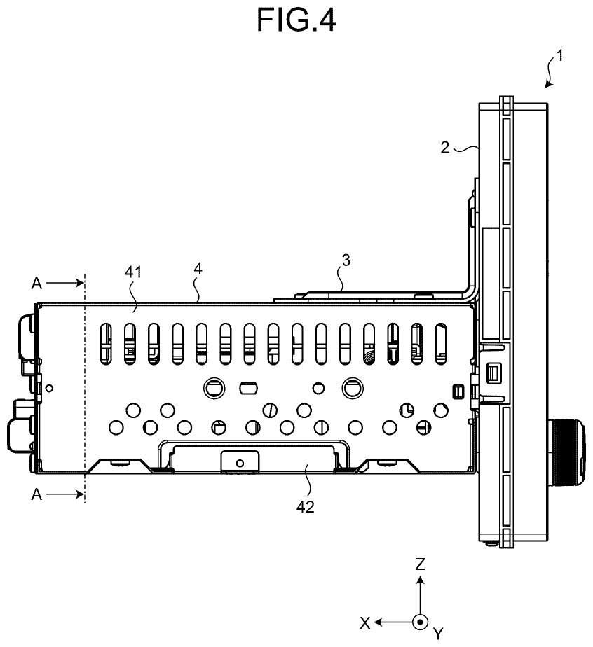

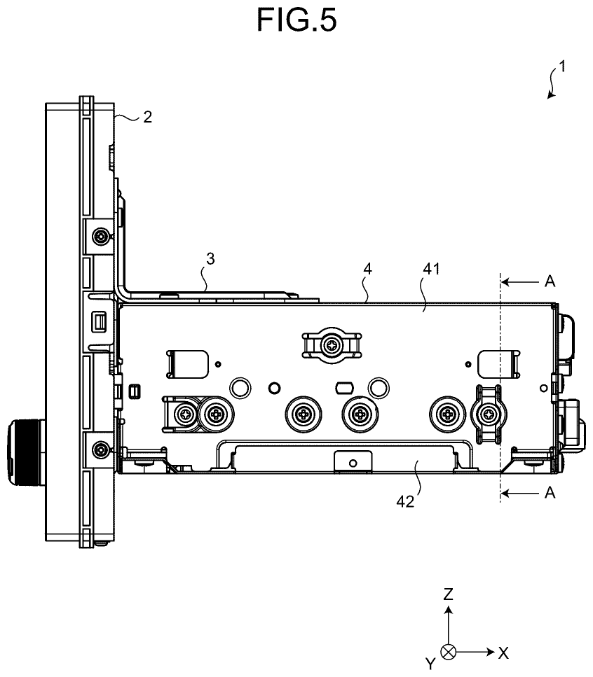

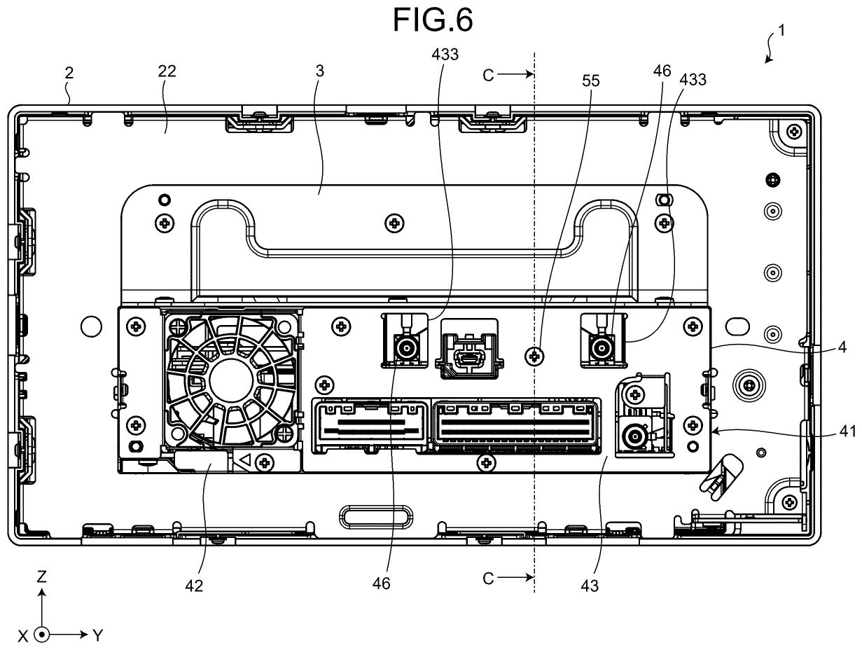

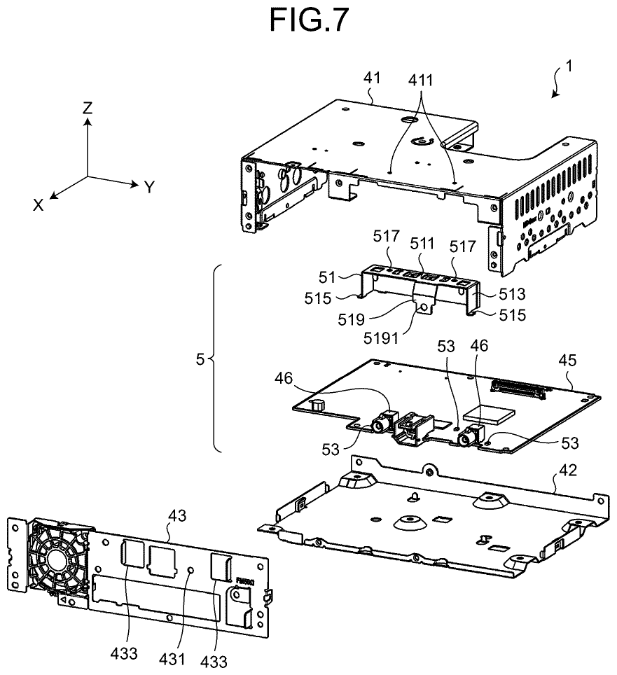

First, a configuration of a display device 1 to which a shield structure 5 according to the present embodiment is applied is described with reference to FIGS. 1 to 7. FIG. 1 is a front view illustrating an example of a configuration of a display device 1 to which a shield structure 5 according to an embodiment is applied. FIG. 2 is a plan view illustrating an example of the configuration of the display device 1 of FIG. 1. FIG. 3 is a bottom view illustrating an example of the configuration of the display device 1 of FIG. 1. FIG. 4 is a left side view illustrating an example of the configuration of the display device 1 of FIG. 1. FIG. 5 is a right side view illustrating an example of the configuration of the display device 1 of FIG. 1. FIG. 6 is a rear view illustrating an example of the configuration of the display device 1 of FIG. 1. FIG. 7 is an exploded perspective view illustrating an example of the configuration of the display device 1 of FIG. 1.

As illustrated in FIGS. 1 to 6, a display unit 2 of the display device 1 is formed in, for example, a flat sheet shape. As the display unit 2, for example, a display device such as a liquid crystal display (LCD) or an organic EL (electro-luminescence) display can be used as appropriate.

As illustrated in FIG. 1, a screen 21 and operation units 23a to 23c are provided on the front surface side (the Y-Z plane on the X-side) of the display unit 2. Each of the operation units 23a to 23c is an operation component that accepts a user's operation. The operation unit 23a is, for example, a touch panel, and is provided on the screen 21. The operation unit 23b is, for example, an operation button, and is provided laterally to the screen 21 in the example of FIG. 1. The operation unit 23c is, for example, an operation dial, and is provided laterally to the screen 21 in the example of FIG. 1.

The operation unit 23a as a touch panel is, for example, provided on the screen to form a touch panel display, but in addition to or instead of this, may be provided in another portion or may not be provided. The operation units 23b and 23c may be obtained by using a touch panel display. Other operation components than the operation units 23a to 23c may be provided on the front surface of the display unit 2. In addition to or instead of these operation components, an input device that acquires voice or motion related to a user's operation, such as a microphone or a camera, may be used.

As illustrated in FIG. 6, a frame 22 is provided on the back surface side (the Y-Z plane on the X+ side) of the display unit 2. The frame 22 is formed of, for example, a sheet-like member made of a material having high conductivity, such as a metal, and supports each part of the display unit 2. For example, the frame 22 supports constituent components of the display unit 2, such as the screen 21 and the operation units 23a to 23c, together with a printed circuit board for displaying (not illustrated), and is attached to a frame body formed of resin or the like. Various electronic components such as an electronic component that processes signals from the operation units 23a to 23c, an electronic component for performing transmission and reception of various signals with a main body unit 4, and an electronic component that controls displaying by the screen 21 on the basis of signals from the main body unit 4 are mounted on the printed circuit board for displaying (not illustrated) built in the display unit 2.

As illustrated in FIGS. 2, and 4 to 6, the display unit 2 of the display device 1 is fixed to the main body unit 4 by a connection unit 3. The connection unit 3 is formed by, for example, performing bending (for example, pressing) to bend, for example, a sheet-like member into an L shape. The connection unit 3 is formed of, for example, a metal material, but may be formed of another material such as a resin material.

The connection unit 3 is fixed in an attachable and detachable manner to the frame 22 on the back surface side (the Y-Z plane on the X+ side) of the display unit 2 by using, for example, a fixing member such as a screw. Further, the connection unit 3 is fixed in an attachable and detachable manner to the upper surface side (the X-Y plane on the Z+ side) of a sheet metal housing 41 of the main body unit 4 by using, for example, a fixing member such as a screw. Thus, the display unit 2 and the main body unit 4 are fixed in an attachable and detachable manner by being fixed to the connection unit 3.

The connection unit 3 needs only to be able to fix the display unit 2 and the main body unit 4 in an attachable and detachable manner, and may have another shape. In the fixing of the display unit 2 and the main body unit, the connection unit 3 may not be provided, or may be one used in combination with another fixing unit. Examples of the other fixing unit include a fixing unit using an interference fit, and a fixing unit based on fitting of a fitting claw and a recess (hole), such as a snap-fit, formed in its connection portion. The frame 22 of the display unit 2 and the sheet metal housing 41 may be an integrally formed component.

As illustrated in FIGS. 2 to 7, the main body unit 4 is formed in a box shape by, for example, attaching a bottom sheet 42 and a back sheet 43 to the sheet metal housing 41. The sheet metal housing 41, the bottom sheet 42, and the back sheet 43 constitute a housing of the main body unit 4.

As illustrated in FIGS. 2 to 7, the sheet metal housing 41 is formed by, for example, performing bending (for example, pressing) to bend, for example, a sheet-like member made of a material having high conductivity, such as a metal, into a rectangular U shape (square U shape). The sheet metal housing 41 has an upper surface (the X-Y plane on the Z+ side) portion of the box-shaped main body unit 4 and side surface (the X-Y plane on each of the Y+ side and the Y− side) portions extending from both end portions in the Y direction of the upper surface portion toward the Z− side along the Z-X plane. The sheet metal housing 41 is subjected to GND connection by a method such as electrical connection to a component of the ground potential, such as a chassis of a vehicle.

As illustrated in FIGS. 2 to 7, each of the bottom sheet 42 and the back sheet 43 is formed by, for example, performing pressing on a sheet-like member made of a material having high conductivity, such as a metal. In the back sheet 43, holes 433 are provided in positions facing connectors 46 that are surface-mounted on a printed circuit board 45 in a state where the main body unit 4 is attached. Thereby, an external connector provided on a connection cable or the like that performs input and output on the main body unit 4 can be connected to a connector 46 surface-mounted on the printed circuit board 45.

Two or more of the sheet metal housing 41, the bottom sheet 42, and the back sheet 43 may be an integrally formed component. Further, each of the sheet metal housing 41, the bottom sheet 42, and the back sheet 43 may be a member formed by combining two or more components.

As illustrated in FIG. 7, a printed circuit board 45 is provided inside the main body unit 4. The printed circuit board 45 is fixed in an attachable and detachable manner to the bottom sheet 42 by using, for example, a fixing member (not illustrated) such as a screw. The entire periphery of the printed circuit board 45 is surrounded by the frame 22 of the display unit 2, the sheet metal housing 41, the bottom sheet 42, and the back sheet 43 to such a degree that a shielding effect can be obtained.

Various electronic components such as an electronic component that performs transmission and reception of various signals with the outside of the display device 1 or the display unit 2, an electronic component that processes signals from the outside or the display unit 2, and an electronic component that generates various signals to be outputted to the outside of the display device 1 or the display unit 2 are mounted on the printed circuit board 45. These electronic components are surface-mounted by, for example, an SMT (surface mount technology) process.

On the printed circuit board 45, a wiring pattern (not illustrated) that arbitrarily connects electronic components, a power supply line, and a grounding conductor is formed.

As illustrated in FIG. 7, the electronic components surface-mounted on the printed circuit board 45 include at least one connector 46. For example, the at least one connector 46 of the printed circuit board 45 connects an in-vehicle sensor, an in-vehicle speaker, another display device, an ECU (electronic control unit), etc., and the display device 1 such that both can communicate with each other. Thus, electronic components such as the connector 46 are EMC (electromagnetic environmental compatibility) measure target components that are required to be subjected to an EMC measure in order to suppress inflow of noise from the outside to the display device 1 and outflow of noise to the outside. The connector 46 is electrically connected to at least the grounding conductor of the wiring pattern formed on the printed circuit board 45.

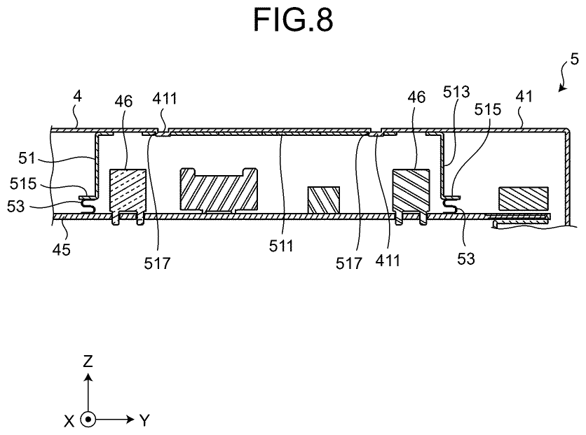

Under such circumstances, regarding the connector 46 as an EMC measure target component, the display device 1 according to the present disclosure is provided with a shield structure 5 that forms an electromagnetic wave shield. FIG. 8 is a cross-sectional view illustrating an example of a configuration of the shield structure 5 of FIG. 7. FIG. 8 illustrates an example of the A-A cross section of FIGS. 2 to 5. As illustrated in FIGS. 7 and 8, the shield structure 5 includes a connector shield metal part 51 and elastic members 53.

The connector shield metal part 51 is, inside the main body unit 4, placed on the side (the Z+ side) of the printed circuit board 45 on which the connector 46 is surface-mounted. The connector shield metal part 51 is electrically connected in a contact manner to the sheet metal housing 41 subjected to GND connection. The connector shield metal part 51 is formed by, for example, performing bending (for example, pressing) to bend, for example, a sheet-like member made of a material having high conductivity, such as a metal. The connector shield metal part 51 has an upper surface portion 511 (a portion on the Z+ side). Further, the connector shield metal part 51 has a side surface portion 513 extending from both side surface sides (the Y+ side and the Y− side) and the front surface side (the X− side) of the upper surface portion 511 in a direction toward the printed circuit board 45 (the Z− side) in the state where the connector shield metal part 51 is attached inside the main body unit 4. Similarly, the connector shield metal part 51 has a fixed portion 519 extending from the back surface side (the X+ side) of the upper surface portion 511 in a direction toward the printed circuit board 45 (the Z− side) in the state where it is attached inside the main body unit 4.

Thus, in the state where it is attached inside the main body unit 4, the connector shield metal part 51 has a shape that covers four surfaces of the connector 46 on the upper surface side (the Z+ side), both side surface sides (the Y+ side and the Y− side), and the front surface side (the X− side). That is, in a state where the main body unit 4 is assembled, the entire periphery of the connector 46 is further surrounded by the bottom sheet 42, the back sheet 43, and the connector shield metal part 51 to such a degree that a shielding effect can be obtained. Therefore, the connector shield metal part 51 can, by its material and shape, reduce emission noise from the connector 46.

In the state where it is attached inside the main body unit 4, the gap between the connector shield metal part 51 and the printed circuit board 45 may be determined from the viewpoint of reducing emission noise. As an example, end portions on the printed circuit board 45 side (the −Z side) of the side surface portion 513 and the fixed portion 519 extend from the upper surface portion 511 to such a degree that the gap with the elastic member 53 mounted on the printed circuit board 45 is, for example, about 1 mm as a minimum gap.

The material and the sheet thickness of the connector shield metal part 51 may be selected with the intention of suppressing breakage and failure from the viewpoint of vibration resistance and impact resistance. As an example, in order to prevent deformation of the connector shield metal part 51 due to vibration and impact transmitted from the vehicle, the connector shield metal part 51 is formed of a steel sheet (SECC) having a sheet thickness of about 0.6 mm and subjected to electrogalvanization.

The elastic member 53 is surface-mounted on the side (the Z+ side) of the printed circuit board 45 on which the connector 46 is surface-mounted, that is, the side facing the connector shield metal part 51 in the state where it is attached inside the main body unit 4. Regarding a circuit configuration mounted on the printed circuit board 45, the elastic member 53 is electrically connected to the grounding conductor.

The elastic member 53 is placed according to the placement and shape of the connector shield metal part 51. Specifically, the elastic member 53 is placed in a position facing a connection portion 515 of the connector shield metal part 51 in the state where it is attached inside the main body unit 4. For example, the connection portion 515 extends in a direction along the printed circuit board 45 from the side surface portion 513 in an end portion on the printed circuit board 45 side.

In the state where it is attached inside the main body unit 4, the connection portion 515 of the connector shield metal part 51 is in contact with the elastic member 53 surface-mounted on the printed circuit board 45. By this contact, the connector shield metal part 51 and the printed circuit board 45 come into conduction via the elastic member 53.

The elastic member 53 is formed of, for example, a material having high conductivity, such as a metal. Each of the elastic members 53 needs only to, in the state where it is attached inside the main body unit 4, be able to bias the connector shield metal part 51 toward the sheet metal housing 41, that is, in a direction away from the printed circuit board 45 (the Z+ side). Thus, the elastic member 53 is, for example, a leaf spring, but may be one having elasticity by means of another shape or material, such as a coil spring.

The number and shape of elastic members 53 can be changed as appropriate. For example, the elastic member 53 may be a DIP component having a shape running along the side surface portion 513 of the connector shield metal part 51.

The elastic member 53 is not limited to the case of being surface-mounted on the printed circuit board 45, and may be fixed to the connector shield metal part 51. In this case, the printed circuit board 45 may be provided with a connection portion for contact with the elastic member 53 fixed to the connector shield metal part 51. This connection portion needs only to be electrically connected to the grounding conductor of the printed circuit board 45.

These days, from the viewpoint of stabilizing board mounting quality, reducing costs related to facilities and jigs, and reducing the number of steps of the mounting process, there is a tendency to reduce the weight of the soldering process in board mounting and switch the entire process of board mounting from a DIP process to an SMT (surface mount technology) process. Under such circumstances, in the shield structure 5 according to the present embodiment, the connector shield metal part 51 and the printed circuit board 45 are brought into contact with each other via the elastic member 53. Thereby, the connector shield metal part 51 can be a component that does not need a DIP (dual in-line package) process of soldering to the printed circuit board 45.

In the case where it is attempted to perform board mounting by the SMT process, there has been room for consideration for how GND connection of the printed circuit board should be obtained by a shield member used for an EMC measure. Under such circumstances, in the shield structure 5 according to the present embodiment, the grounding conductor of the printed circuit board 45 can be subjected to GND connection via the sheet metal housing 41 by bringing the connector shield metal part 51 into contact with the elastic member 53 on the printed circuit board 45.

### Second Embodiment

Herein, another configuration for subjecting the printed circuit board 45 to GND connection by means of the connector shield metal part 51 will now be described. In the present embodiment, configurations different from the shield structure 5 according to the first embodiment are mainly described, and a description of common configurations is omitted as appropriate.

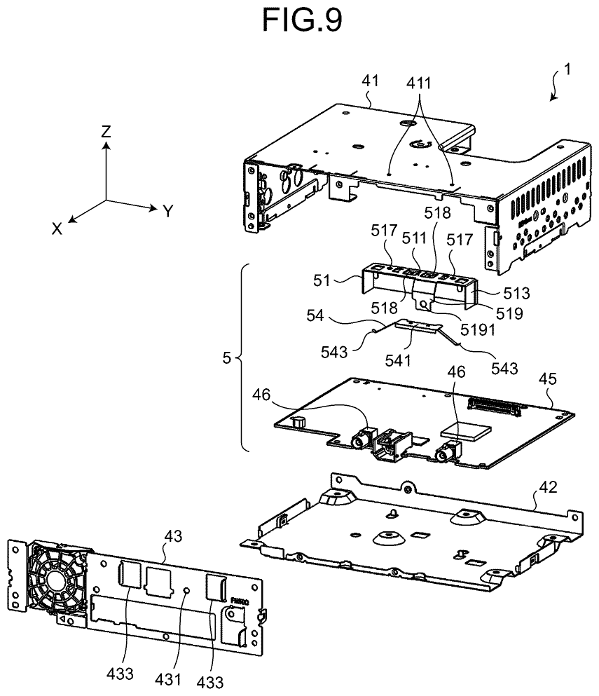

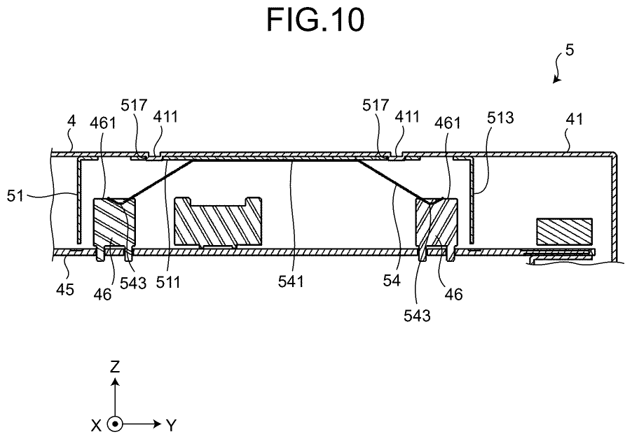

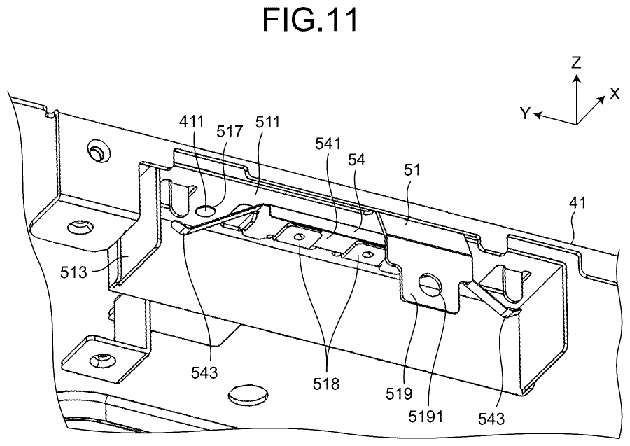

FIG. 9 is an exploded perspective view illustrating another example of the configuration of the display device 1 of FIG. 1. FIG. 10 is a cross-sectional view illustrating an example of a configuration of the shield structure 5 of FIG. 9. FIG. 10 illustrates an example of the A-A cross section of FIGS. 2 to 5. FIG. 11 is a perspective view illustrating an example of the configuration of the shield structure 5 of FIG. 9.

In the shield structure 5 according to the present embodiment, the connector 46 surface-mounted on the printed circuit board 45 has, for example, a housing formed of a conductive material such as a metal.

As illustrated in FIGS. 9 and 10, in the shield structure 5 according to the present embodiment, an elastic member 53 is not surface-mounted on the printed circuit board 45. In the state where it is attached inside the main body unit 4, the gap between the connector shield metal part 51 and the printed circuit board 45 may be determined from the viewpoint of reducing emission noise. For example, end portions on the printed circuit board 45 side (the −Z side) of the side surface portion 513 and the fixed portion 519 extend from the upper surface portion 511 to such a degree that the gap with the printed circuit board 45 is, for example, about 1 mm as a minimum gap. That is, the side surface portion 513 according to the present embodiment is longer than the side surface portion 513 according to the first embodiment by an amount equivalent to the elastic member 53.

As illustrated in FIGS. 9 to 11, the shield structure 5 according to the present embodiment includes an elastic member 54 in place of the elastic member 53.

The elastic member 54 is formed by, for example, performing bending (for example, pressing) to bend, for example, a sheet-like member made of a material having high conductivity, such as a metal. The elastic member 54 has a fixed portion 541 formed in a shape running along the upper surface portion 511 of the connector shield metal part 51, and arm portions 543 extending from end portions of the fixed portion 541.

As illustrated in FIGS. 9 and 11, fixed portions 518 are provided on the upper surface portion 511 of the connector shield metal part 51. The fixed portion 518 extends in a claw shape from a part of the upper surface portion 511, for example. The fixed portion 518 forms, with the back surface side (the Z− side) of the upper surface portion 511, a gap according to the thickness of the fixed portion 541 of the elastic member 54.

As illustrated in FIG. 11, the elastic member 54 is inserted into the gap between the upper surface portion 511 and the fixed portion 518 of the connector shield metal part 51. The fixed portion 541 of the elastic member 54 inserted between the upper surface portion 511 and the fixed portion 518 of the connector shield metal part 51 is sandwiched and supported by the upper surface portion 511 and the fixed portion 518. The elastic member 54 thus fixed to the connector shield metal part 51 is electrically connected to the connector shield metal part 51.

As illustrated in FIGS. 9 to 11, in the state where it is attached inside the main body unit 4, the arm portion 543 of the elastic member 54 extends from an end portion of the fixed portion 541 to the position of the connector 46 laterally (the Y direction) and downward (the Z− side). An end portion of the arm portion 543 opposite to the fixed portion 541 is in contact with an upper surface portion 461 of the connector 46 to bias the upper surface portion 461 toward the printed circuit board 45 (the Z− side), and is electrically connected thereto.

In the state where it is attached inside the main body unit 4, the gap between the connector shield metal part 51 and the printed circuit board 45 may be determined from the viewpoint of reducing emission noise. As an example, end portions on the printed circuit board 45 side (the −Z side) of the side surface portion 513 and the fixed portion 519 extend from the upper surface portion 511 to such a degree that the gap with the elastic member 53 mounted on the printed circuit board 45 is, for example, about 1 mm as a minimum gap.

The degree of biasing (for example, spring pressure) by the elastic member 54, such as the spring material, the spring sheet thickness, the spring arm length, the spring arm width, and the amount of pushing, may be selected with the intention of preventing coming-off of the point of contact with the connector 46 from the viewpoint of vibration resistance and impact resistance. As an example, the degree of biasing is determined while deformation due to vibration and impact transmitted from the vehicle is taken into consideration, and the elastic member 54 is formed of SUS 304 having a sheet thickness of about 0.2 mm. For proper biasing to the connector 46, that is, in order to apply appropriate pretension, as illustrated in FIG. 10, an end portion on the connector 46 side of the arm portion 543 of the elastic member 54 overlaps with the connector 46. The width of this overlap is, for example, about 1 mm.

Although FIGS. 9 to 11 illustrate, as an example, an elastic member 54 having two arm portions 543, the configuration is not limited thereto. The number of arm portions 543 may be one or a plural number of three or more according to the number of connectors 46, which are EMC measure target components. In place of two or more arm portions 543, an elastic member 54 having at least one of the two or more arm portions 543 may be used.

Although FIGS. 9 to 11 illustrate, as an example, an elastic member 54 fixed to the upper surface portion 511 of the connector shield metal part 51, the configuration is not limited thereto. The elastic member 54 may be fixed to the side surface portion 513 of the connector shield metal part 51.

Thus, in the shield structure 5 according to the present embodiment, an elastic member 54 to be in contact with the connector 46 is provided on the connector shield metal part 51. By using this configuration, the housing of the connector 46 can be subjected to GND connection via the elastic member 54. That is, in the shield structure 5 according to the present embodiment, since the connector 46 is subjected to GND connection by the connector shield metal part 51, GND connection can be ensured without directly connecting the connector shield metal part 51 to the printed circuit board 45, and at the same time the shape of the connector shield metal part 51 can be simplified.

Further, in the shield structure 5 according to the present embodiment, the need of the step of surface-mounting the elastic member 53 on the printed circuit board 45 can be eliminated, and the need of complicated alignment between the connector shield metal part 51 and the elastic member 53 can be eliminated.

Further, in the shield structure 5 according to the present embodiment, the connector shield metal part 51 is provided with a point of spring contact to be directly connected to the connector 46 in a short path; thereby, the path of GND connection can be shortened, and noise emitted from the path can be reduced.

The shield structure 5 according to the first embodiment and the shield structure 5 according to the second embodiment can be combined. That is, the connector shield metal part 51 of the shield structure 5 according to the present disclosure may be one that subjects the printed circuit board 45 to GND connection via the elastic member 53 to indirectly subject the connector 46 to GND connection and furthermore directly subjects the connector 46 to GND connection via the elastic member 54.

With regard to a configuration in which a connector shield metal part is integrated with a sheet metal housing

The connector shield metal part 51 according to the present disclosure is fixed to and integrated with the sheet metal housing 41 on the mounting surface side of the printed circuit board 45. Herein, regarding the shield structure 5 according to each of the above-described embodiments, fastening of the connector shield metal part 51 and the sheet metal housing 41 will now be described.

Inside the main body unit 4, the connector shield metal part 51 is placed on the side (the Z+ side) of the printed circuit board 45 on which the connector 46 is surface-mounted, and is fixed to and integrated with the sheet metal housing 41 subjected to GND connection.

Specifically, as illustrated in FIGS. 7 to 11, fixed portions 517 are provided on the upper surface portion 511 of the connector shield metal part 51. Further, fixed portions 411 are provided on the upper surface side (the X-Y plane on the Z+ side) of the sheet metal housing 41 that faces the upper surface portion 511 of the connector shield metal part 51 in the state where it is attached inside the main body unit 4. The fixed portions 411 and 517 form a dowel-swage structure, and fasten the connector shield metal part 51 and the sheet metal housing 41. Although FIGS. 7 and 8 illustrate, as an example, a case where the fixed portion 411 is formed as a dowel, either of the fixed portions 411 and 517 may be formed as a dowel.

Thereby, the connector shield metal part 51 and the sheet metal housing 41 can be fastened without making a hole in the top surface (upper surface) of the sheet metal housing 41. Thus, for example, even when the main body unit 4 receives water due to a liquid such as a beverage spilt by an occupant in the vehicle interior or water droplets from an air conditioner duct, it is possible to inhibit water from entering inside the main body unit 4 from the top surface of the sheet metal housing 41, that is, waterproofness can be improved, and the occurrence of a short circuit or the like can be suppressed.

There is a demand for a technology that, when it is attempted to perform mounting of the connector shield metal part 51 by the SMT process, integrates a shield member used for an EMC measure with components on the mounting surface side of the printed circuit board. Under such circumstances, in the shield structure 5 according to the present disclosure, the integration can be made by swaging and fixing the connector shield metal part 51 to the sheet metal housing 41 on the mounting surface side of the printed circuit board 45 on which the connector 46 is surface-mounted.

In the shield structure 5 according to the present disclosure, since the connector shield metal part 51 can be fastened to the sheet metal housing 41 by swaging, the connector shield metal part 51 can be a DIP-less component that does not need soldering to the printed circuit board 45. Further, in the shield structure 5 according to the first embodiment, the electrical connection between the connector shield metal part 51 and the printed circuit board 45 is obtained via the elastic member 53. Similarly, in the shield structure 5 according to the second embodiment, the electrical connection between the connector shield metal part 51 and the connector 46 is obtained via the elastic member 54. Thus, in the shield structure 5 according to the present disclosure, regarding the connector shield metal part 51, the need of a DIP process is eliminated, and a point of contact with the printed circuit board 45 is eliminated; thereby, the board design of the main body unit 4 and the shape of the connector shield metal part 51 can be simplified.

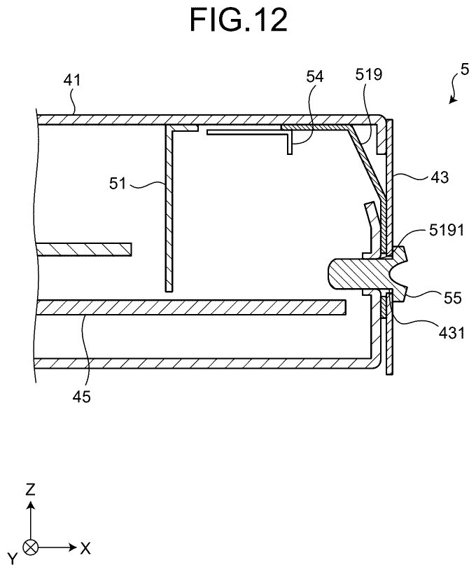

FIG. 12 is a cross-sectional view illustrating an example of the configuration of the display device 1 of FIG. 1. FIG. 12 illustrates an example of the C-C cross section of FIGS. 2, 3, and 6. FIG. 12 illustrates an example of the shield structure 5 according to the second embodiment.

As illustrated in FIGS. 7, 9, 11, and 12, in the shield structure 5 according to the present disclosure, a hole 5191 is provided in the fixed portion 519 extending downward (the Z− side) from the back surface side (the X+ side) of the upper surface portion 511 of the connector shield metal part 51. As illustrated in FIGS. 7, 9, and 12, in the back sheet 43, a hole 431 is provided in a position facing the hole 5191 of the connector shield metal part 51 in the state where it is attached inside the main body unit 4.

Then, as illustrated in FIGS. 6 and 12, in the shield structure 5 according to the present disclosure, a common fixing member 55 such as a screw made of a material having high conductivity, such as a metal, is inserted into the hole 5191 of the connector shield metal part 51 and the hole 431 of the back sheet 43. Thereby, the hole 5191 of the connector shield metal part 51 and the hole 431 of the back sheet 43 are electrically connected in a direct manner or via the fixing member 55.

Thus, by using the configuration in which the back sheet 43 and the connector shield metal part 51 are fastened by the screw, the path of GND connection between the connector shield metal part 51 and the back sheet 43 can be further shortened, while being swaged and fastened to the top surface (upper surface) of the sheet metal housing 41. On the back surface side of the main body unit 4, a vehicle harness is connected to the connector 46. Thus, it is necessary to prevent a situation where noise emitted from the connector 46 runs on the vehicle harness and is emitted to peripheral devices. Under such circumstances, in the shield structure 5 according to the present disclosure, since the path of GND connection between the connector shield metal part 51 and the back sheet 43 can be further shortened, noise emitted from this path to the back surface side of the main body unit 4 can be further reduced.

Thus, in the shield structure 5 according to the present disclosure, the connector shield metal part 51 is integrated with the components on the mounting surface side of the printed circuit board 45 by dowel-swage fastening with the top surface (upper surface) of the sheet metal housing 41 and fastening by the screw with the back sheet 43. By using this configuration, resonance of the connector shield metal part 51 due to vibration transmitted from the vehicle can be suppressed.

According to at least one of the embodiments described hereinabove, an EMC measure of board-mounted components can be taken in the case where the process of board mounting is performed by SMT.

According to the present disclosure, an EMC measure of board-mounted components can be taken in the case where the process of board mounting is performed by SMT. The effect mentioned here is not necessarily a limitative one, and any of the effects described in the present specification is possible.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A shield structure comprising:
a printed circuit board that is placed inside a grounded housing and on which at least one electronic component including a connector connected outside is surface-mounted;
an elastic member placed on a mounting surface side of the printed circuit board, inside the housing; and
a connector shield metal part placed on the mounting surface side, inside the housing and formed in a shape covering the connector, wherein
the connector shield metal part directly contacts and is electrically connected to the housing, and is electrically connected to the connector via the elastic member in a state where the connector shield metal part is attached to the housing.

2. The shield structure according to claim 1, wherein
a wiring pattern electrically connecting the connector and the elastic member is formed on the printed circuit board,
the elastic member is surface-mounted on the printed circuit board and biases the connector shield metal part toward the housing in a state where the connector shield metal part is attached to the housing, the connector shield metal part being in contact with the elastic member from the mounting surface side, and
the connector shield metal part is electrically connected to the connector via the printed circuit board in a state where the connector shield metal part is attached to the housing.

3. The shield structure according to claim 1, wherein
a wiring pattern electrically connecting the connector and the elastic member is formed on the printed circuit board,
the elastic member is fixed to the connector shield metal part and biases the connector shield metal part toward the housing in a state where the connector shield metal part is attached to the housing, the connector shield metal part being in contact with the elastic member from the mounting surface side, and
the connector shield metal part is electrically connected to the connector via the printed circuit board in a state where the connector shield metal part is attached to the housing.

4. The shield structure according to claim 1, wherein
the elastic member has a fixed portion fixed to the connector shield metal part and an arm portion extending from the fixed portion,
the arm portion is in contact with the connector from the mounting surface side and biases the connector toward the printed circuit board in a state where the connector shield metal part is attached to the housing, and
the connector shield metal part is electrically connected to the connector without interposing the printed circuit board in a state where the connector shield metal part is attached to the housing.

5. The shield structure according to claim 4, wherein
the fixed portion of the elastic member is fixed to an upper surface portion of the connector shield metal part, the upper surface portion being in contact with the housing.

6. The shield structure according to claim 4, wherein
the fixed portion of the elastic member is fixed to a side surface portion of the connector shield metal part, the side surface portion extending from an upper surface portion of the connector shield metal part toward the printed circuit board, the upper surface portion being in contact with the housing.

7. An in-vehicle device comprising:
the shield structure according to claim 1; and
the housing electrically connected to a component of a vehicle having a ground potential, wherein
an upper surface portion of the connector shield metal part is swaged and fastened to the housing, the upper surface portion being in contact with the housing.

8. An in-vehicle device comprising:
the shield structure according to claim 1; and
the housing electrically connected to a component of a vehicle having a ground potential, wherein
the connector shield metal part has a fixed portion extending from a side of an upper surface portion toward the printed circuit board, the side of the upper surface portion being closer to a back surface of the housing, the upper surface portion being in contact with the housing, and
the fixed portion of the connector shield metal part and a back surface side of the housing are fastened by a screw.

9. The in-vehicle device according to claim 8, wherein
the upper surface portion of the connector shield metal part is swaged and fastened to the housing.
